(19) United States
(12) Patent Application Publication
(10) Pub. No.: US 2004/0208209 A1
(43) Pub. Date: Oct. 21, 2004

(54) Fabrication method of semiconductor laser device

(75) Inventor: Jun Okazaki, Nara-shi (JP)

Correspondence Address: NIXON & VANDERHYE, PC, 1100 N GLEBE ROAD, 8TH FLOOR, ARLINGTON, VA, 22201-4714, US

(73) Assignee: SHARP KABUSHIKI KAISHA, Osaka (JP)

(21) Appl. No.: 10/801,032

(22) Filed: Mar. 16, 2004

(30) Foreign Application Priority Data
Apr. 18, 2003 (JP) 2003-114894

(51) Int. Cl. H01S 3/04; H01S 5/00

(52) U.S. Cl. 372/36

(57) ABSTRACT

An object of the invention to provide a semiconductor laser device fabrication method that can suppress inadvertent crosstalk while maintaining high relative position accuracy for a plurality of laser elements. In order to achieve this object, a plurality of emission sections are first formed on a single substrate, and the substrate is mounted on a sub mount. Then, the substrate on the sub mount is cut at a midway point between the emission sections. A laser device so fabricated includes two laser elements that are monolithically formed, thereby providing the laser elements with high relative position accuracy. Further, the substrate is cut between the laser elements, thereby preventing transfer of heat or electricity through the substrate. As a result, inadvertent thermal and electrical crosstalk can be effectively suppressed.

This Nonprovisional application claims priority under 35 U.S.C. § 119(a) on patent application Ser. No. 2003/114,894 filed in Japan on Apr. 18, 2003, the entire contents of which are hereby incorporated by reference.

### FIELD OF THE INVENTION

The present invention relates to fabrication methods of a semiconductor laser device including a plurality of semiconductor laser elements on a sub mount.

### BACKGROUND OF THE INVENTION

There have been proposed laser devices that can emit two laser beams (multi-beam laser device, MB laser device), as disclosed, for example, in Japanese Publication for Unexamined Patent Application No. 145779/1991 (Tokukaihei 3-145779, published on Jun. 20, 1991) (hereinafter “Publication 1”).

Such MB laser device have been used, for example, for CD/DVD players for reproducing both CD and DVD, and laser beam printers (LBP, digital copying machine, etc.) that expose a photoreceptor by irradiation of two laser beams.

In these applications, the MB laser device uses two laser beams of different wavelengths.

One of the requirements of the MB laser device when it is used in a printer is to simultaneously emit two laser beams. This has called for a configuration that enables two laser elements to be driven both simultaneously and independently.

Currently, two types of MB laser devices are available: those employing the monolithic structure, and those employing the hybrid structure. In the monolithic structure, a semiconductor laser device that can emit two laser beams is placed on a single semiconductor substrate, whereas, in the hybrid structure, two semiconductor laser devices, each emitting a single laser beam, are respectively placed on separate semiconductor substrates.

In the monolithic structure, two laser elements are processed out of a single substrate (wafer). This is advantageous in improving the position accuracy of the laser elements.

However, a problem is posed when the two laser beams are activated simultaneously. Specifically, an electrical spike (fluctuation) may be introduced into the driving voltage of an activated laser element when the other laser element is activated (electrical crosstalk occurs).

FIG. 13 is an explanatory view illustrating how such electrical crosstalk occurs.

As shown in FIG. 13, the driving voltage of laser element A in an ON state (activated state) is spiked (noise is introduced) when ON/OFF of laser element B is switched. The spike is caused by an electrical noise that transmits through the substrate on which the laser elements A and B are mounted.

Note that, the notations Pw1 and Pw2 in FIG. 13 are pulse widths of the respective driving voltages for the laser element A and laser element B, wherein Pw1 is 120 nsec., and Pw2 is 30 nsec. The duty was 50% in the measurement of FIG. 13.

In addition to the electrical crosstalk, the MB laser device of a monolithic structure also causes thermal crosstalk.

FIG. 14 is an explanatory view of thermal crosstalk, showing a laser output of the laser element A (as received by a photo-receiving element) with respect to a predetermined driving current. FIG. 14 also illustrates a driving voltage of the laser element B.

As shown in FIG. 14, when the laser element B is turned ON, the laser output of the laser element A is decreased by the generated heat of the laser element B, even though the driving current of the laser element A remains the same (P11>P13, P2>P3).

Such a decrease of laser output (thermal crosstalk) is believed to be caused by the generated heat of the laser element B (heat of oscillation) when the heat transfers to the laser element A through the substrate.

Thus, owning to the fact that the two laser elements are mounted on a single substrate, the MB laser device of a monolithic structure causes electrical and thermal crosstalk, with the result that the laser characteristic (laser output) fluctuates. This poses a problem when the MB laser device is used for a printer. Specifically, print quality suffers as the size or shape of a print spot deviates from the specific dimensions depending on the state of oscillation of the adjacent laser elements.

Note that, “Duty” in FIG. 14 indicates a ratio of ON time with respect to the pulse width of the driving voltage. That is, the ON time of a laser element is 0.1 msec. when Pw1=1 msec. (fc=1 kHz) and duty=10%. It can be seen from this that the ON time increases and the laser output decreases as the duty increases.

A technique for overcoming such a drawback is disclosed in Japanese Publication for Unexamined Patent Application No. 29618/1994 (Tokukaihei 6-29618, published on Feb. 4, 1994) (hereinafter “Publication 2”). This publication describes a semiconductor laser element in which a middle portion of a layer material with two laser elements (i.e., between the two laser elements) is etched down to a portion of the active layer.

The semiconductor laser element disclosed in this publication provides a long semiconductor path (path that transmits heat or electricity to adjoining emission sources) whose heat conductivity or electrical conductivity is higher than that of air, so as to reduce the cross sectional area of the layer material transmitting heat or electricity. In this way, crosstalk is suppressed.

An MB laser device employing the hybrid structure is described, for example, in Japanese Publication for Unexamined Patent Application No. 112089/1999 (Tokukaihei 11-112089, published on Apr. 23, 1999) (hereinafter “Publication 3”).

In the hybrid MB laser device, two laser elements are respectively formed on separate substrates, and the two laser elements are packaged in a single package almost independently. According to this structure, the two laser elements, which are made contact to each other via electrodes, are separated by a highly insulating layer of air. This makes it difficult for the heat of oscillation of one laser element to transmit to the other laser element.

Further, with the electrodes independently provided for the two laser element, the structure offers more freedom in terms of wire layout.

Turning back to the element structure of Publication 2, the two laser elements are in contact with each other through a buffer layer and a substrate (GaAs substrate), even though the layer material is partially cut. It is therefore impossible to completely eliminate the inadvertent crosstalk.

Further, the laser elements are generally mounted on a substrate with their oscillating sections closer to the sub mount side (on the far side of the substrate). This provides relatively good heat sinking from the sub mount.

However, because the monolithic MB laser device includes a plurality of laser elements on a single substrate, the structure is inevitably of a cathode common layout, making the device incompatible to an anode common laser driver.

In the hybrid structure disclosed in Publication 3, the two independent laser elements are mounted on a device by mechanically adjusting their positions. Accordingly, the accuracy of their relative positions (relative oscillation positions) is determined by the mechanical accuracy. In this regard, the hybrid structure cannot match the monolithic structure that can be fabricated at the accuracy of semiconductor fabrication process such as photolithography.

More specifically, with the currently available mass-production technique, the monolithic structure provides a relative position accuracy of ±2 μm for the two laser elements, while that of the hybrid structure is generally ±10 μm.

In digital copying machines, the irradiated laser beams cannot produce a uniform spot size when the accuracy of the emission sources of the laser elements in a lasing direction is ±2 μm or greater.

### SUMMARY OF THE INVENTION

The present invention was made in view of the foregoing problems, and it is an object of the present invention to provide a fabrication method of a semiconductor laser device that can suppress inadvertent crosstalk while maintaining high relative position accuracy for a plurality of laser elements.

In order to achieve this object, the present invention provides a method for fabricating a semiconductor laser device including a plurality of semiconductor laser elements on a sub mount, the method including: an emission source forming step of stacking a semiconductor layer structure on a single substrate and forming a plurality of emission sources; a mounting step of mounting the substrate with the emission sources on the sub mount; and a substrate cutting step of cutting the substrate between the emission sources, so as to form a plurality of laser elements each including the substrate and an emission source.

The fabrication method of the present invention is used to fabricate a multi-beam laser device (MB laser device) used in electronic devices such as a laser beam printer or a CD/DVD player.

The MB laser device includes a plurality of laser elements (semiconductor laser elements) on a sub mount, so as to emit a plurality of laser beams.

The sub mount is a member used to install the laser elements on a metal stem (anchor) of the electronic device, and the sub mount serves to absorb stress that is generated due to different coefficients of thermal expansion of the laser elements and the metal stem.

The laser elements include a substrate and a semiconductor layer structure (layer structure including emission sources) formed on the substrate. As used herein, “semiconductor layer structure” is a stack of layers made of semiconductor materials. Further, “emission source” refers to a portion of the semiconductor layer structure where laser oscillation occurs (laser beam is emitted).

In order to fabricate such an MB laser device, the fabrication method first forms a plurality of emission sources on a single substrate.

Specifically, in this fabrication step, a semiconductor layer structure is formed on a single substrate, so as to (monolithically) form a series of emission sources.

In the next step of the fabrication method, the substrate with the emission sources is mounted on a sub mount in such a manner that the layer structure is disposed between the substrate and the sub mount (mounting step).

Next, the substrate mounted on the sub mount is cut between the emission sources (substrate cutting step). As a result, a plurality of laser elements are formed that includes the substrate and emission sources (i.e., layer structure including the emission sources) on the sub mount.

In this manner, the fabrication method of the present invention first forms a plurality of emission sources (monolithically) on a single substrate, and the substrate is mounted on the sub mount. Then, the substrate and the layer structure formed on the substrate are cut between the emission sources, so as to form a plurality of laser elements on the sub mount.

Therefore, the fabrication method of the present invention provides a semiconductor laser device that includes a plurality of monolithically formed laser elements. This enables the relative positions (relative oscillation positions) of the laser elements to be accurately maintained.

In the semiconductor laser device fabricated by the fabrication method of the present invention, the substrate is cut between the laser elements, thereby preventing transfer of heat and electricity through the substrate. This effectively suppresses thermal or electrical crosstalk between the laser elements, as in the hybrid laser device.

Further, because the substrate is cut between the laser elements, the semiconductor laser device fabricated by the fabrication method of the present invention does not require electrical contacts through the substrate. This makes it possible to make electrical contacts for the laser elements not only in a cathode common layout (electrodes on the substrate side are commonly connected) but also in an anode common layout (electrodes on the sub mount side are commonly connected).

Further, depending on the wiring pattern of an external device installing the laser device, floating contacts (electrodes of the laser elements are not commonly connected) may be made.

For a fuller understanding of the nature and advantages of the invention, reference should be made to the ensuing detailed description taken in conjunction with the accompanying drawings.

### BRIEF DESCRIPTION OF THE DRAWINGS

FIG. 1 is an explanatory view illustrating a structure of a semiconductor laser device (MB laser device) in one embodiment of the present invention.

FIG. 2 is an explanatory view illustrating a structure of a laser element in the semiconductor laser device of FIG. 1.

FIG. 3(a) and FIG. 3(b) are explanatory views illustrating a fabrication method of the laser element shown in FIG. 2.

FIG. 4 is an explanatory view of a fabrication method of the semiconductor laser device shown in FIG. 1, illustrating a state in which a substrate with emission sources (laser elements) is mounted on a sub mount.

FIG. 5 is an explanatory view of the fabrication method of the semiconductor laser device shown in FIG. 1, illustrating a step of cutting the substrate mounted on the sub mount.

FIG. 6 is an explanatory view illustrating an engine (optical engine) of a laser beam printer (digital copying machine) using the semiconductor laser device of FIG. 1.

FIG. 7 is an explanatory view illustrating an example of a package incorporating the semiconductor laser device of FIG. 1.

FIG. 8 is an explanatory view illustrating a configuration in which an MPD is mounted on the sub mount in the semiconductor laser device of FIG. 1.

FIG. 9 is an explanatory view illustrating timings of monitoring the output of a laser element when ceramic such as insulating SiC is used for the sub mount in the semiconductor laser device of FIG. 1.

FIG. 10(a) through FIG. 10(c) are explanatory views illustrating different wire layouts of the semiconductor laser device of FIG. 1.

FIG. 11 is an explanatory view illustrating a structure of a semiconductor laser device in another embodiment of the present invention.

FIG. 12 is an explanatory view illustrating a relationship between depth of an isolation groove and width of the isolation groove along emission sources in the semiconductor laser device of FIG. 1.

FIG. 13 is an explanatory view illustrating how electrical crosstalk occurs in the semiconductor laser device.

FIG. 14 is an explanatory view illustrating how thermal crosstalk occurs in the semiconductor laser device.

### DESCRIPTION OF THE EMBODIMENTS

One embodiment of the present invention is described below.

A semiconductor laser device according to the present embodiment (“present laser device”) is a multi-beam laser device that can simultaneously emit two laser beams.

The present laser device is applicable to various electronic apparatuses, including, for example, a CD/DVD player that can reproduce both CD (compact disc) and DVD (digital versatile disk), and a laser beam printer (digital copying machine, etc.) that irradiates a photoreceptor with two laser beams.

First, description is made as to a structure of the present laser device.

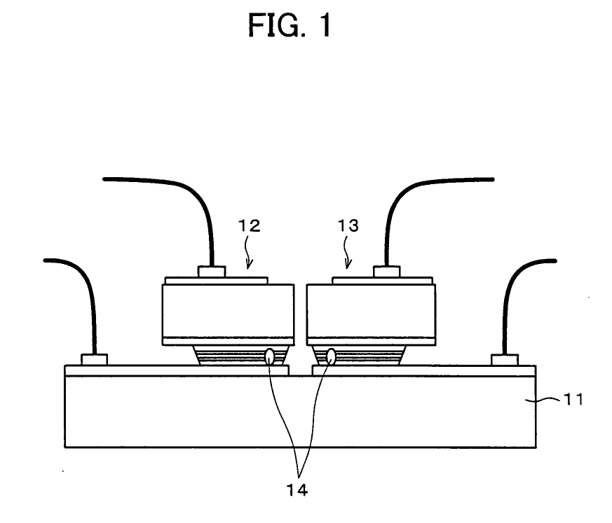

FIG. 1 is an explanatory view illustrating a structure of the present laser device.

As illustrated in FIG. 1, the present laser device includes a first semiconductor laser element 12 and a second semiconductor laser element 13 that are mounted on a sub mount (sub mount substrate) 11 made of insulating SiC.

The present laser device emits a laser beam from an emission source (oscillating region) 14 of each of the laser elements 12 and 13.

The sub mount 11 is used to mount the present laser device on a metal stem (anchor, not shown) of an electronic apparatus. The sub mount 11 is provided to absorb stress that is generated due to different coefficients of thermal expansion between the metal stem and the laser elements 12 and 13.

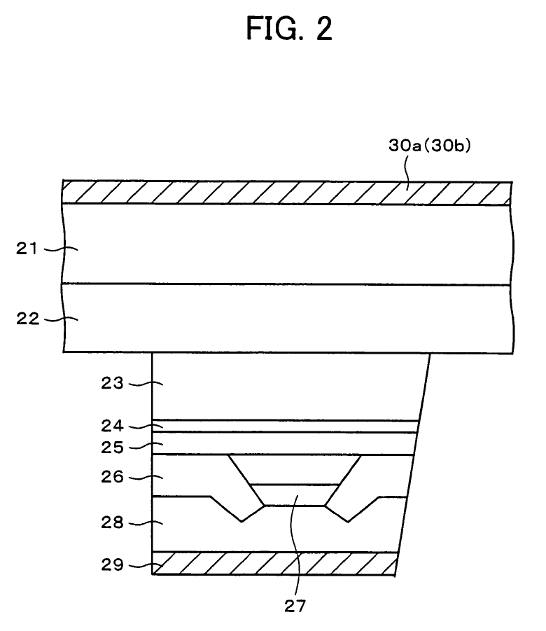

FIG. 2 is an explanatory view illustrating a structure of the laser elements 12 and 13.

As shown in FIG. 2, the laser elements 12 and 13 are structured to include a buffer layer 22, a first clad layer (n-type clad layer) 23, an active layer 24, a second clad layer (p-type clad layer) 25, a current blocking layer 26, a cap layer (ridge) 27, and a contact layer 28. These layers are formed on a substrate 21.

The substrate 21 is made of GaAs (n-type) doped with Si. The buffer layer 22 is also made of GaAs doped with Si. The first clad layer 23 is made of AlGaInP doped with Si. The active layer 24 is made of undoped GaInP. The second clad layer 25 is made of AlGaInP doped with Zn. The current blocking layer 26 is made of GaAs doped with Si. The cap layer 27 is made of GaInP doped with Zn. The contact layer 28 is made of GaAs doped with Zn.

On the front surface of the contact layer 28 is formed an electrode (p electrode) 29. On the back surface of the substrate 21 are formed two ohmic electrodes (n electrodes) 30a and 30b. The ohmic electrodes 30a and 30b correspond to the first semiconductor laser element 12 and the second semiconductor laser element 13, respectively.

In the laser elements 12 and 13, the substrate 21 is about 70 μm thick, and the combined thickness of the buffer layer 22, the cap layer 27, and all the other layers in between is 2 to 3 μm. The contact layer 28 is about 2 μm thick.

A region of the active layer 24 above the cap layer 27 is the emission source 14 shown in FIG. 1.

Further, in each layer of the laser elements 12 and 13, the layer geometry does not vary in a direction perpendicular to the plane of paper in the figure. Accordingly, the emission sources 14 extend in a direction perpendicular to the plane of paper.

The following describes a fabrication method of the present laser device.

First, the buffer layer 22, the first clad layer 23, the active layer 24, the second clad layer 25, and the cap layer 27 are formed in this order on the substrate 21 by epitaxial growth.

Next, the second clad layer 25 and the cap layer 27 are partially etched by mesa etching, using a silicon nitride film as a mask. The current blocking layer 26 is formed on the etched portion.

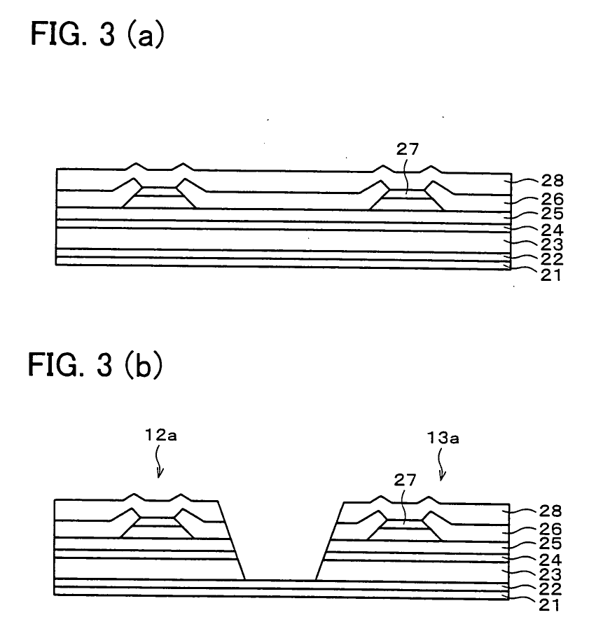

Then, the silicon nitride film is removed, and the contact layer 28 is grown over the entire surface of the exposed layer, so as to obtain a layer structure as shown in FIG. 3(a) (emission source forming step). As shown in FIG. 3(a), the layer structure so formed has two cap layers 27 that are disposed side by side. These cap layers are used to form emission sources (corresponding to the emission sources 14 shown in FIG. 1) in the active layer 24.

In the next step, using a common wet etching technique, a central portion of the layer structure (area between the cap layers 27 or emission sources), from the contact layer 28 to the first clad layer 23, is etched to expose the buffer layer 22. This forms an isolation groove (emission source isolating step).

As a result, emission sections 12a and 13a are isolated from each other, respectively corresponding to the laser elements 12 and 13, as shown in FIG. 3(b). Here, the emission sections 12a and 13a each define a portion of the layer structure including the first clad layer 23, the contact layer 28, and all the other layers in between, and a single cap layer 27 (emission source). In addition, etching is carried out in such a manner that the emission sections 12a and 13a are obtained in a trapezoidal shape.

Note that, Publication 2 or other publications should be referred to for more details of the layer structure of the emission sections 12a and 13a, and the fabrication steps described so far.

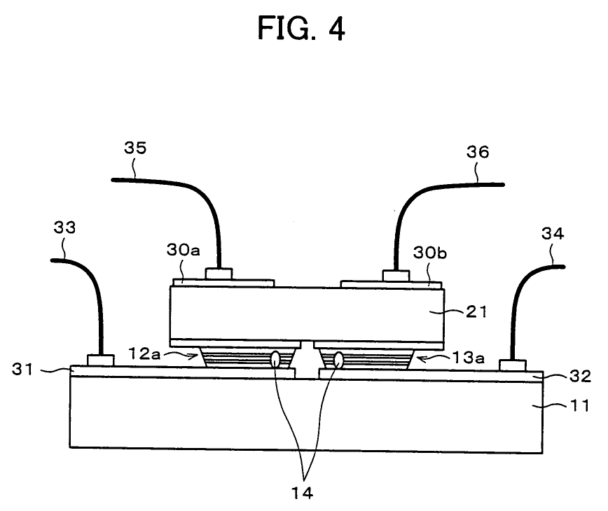

The substrate 21 (monolithic chip) 21 bearing the emission sections 12a and 13a of the layer structure shown in FIG. 3(b) is die bonded on the sub mount 11, as shown in FIG. 4 (mounting step). As a die bond, a solder material such as silver paste or AuSn is used.

Note that, the sub mount 11 has two electrically isolated electrode patterns 31 and 32 that have been formed beforehand. The electrode patterns 31 and 32 are respectively connected to the electrode 29 of the emission section 12a of the first semiconductor laser element 12 and to the electrode 29 of the emission section 13a of the second semiconductor laser element 13.

The electrode patterns 31 and 32 are respectively connected to Au wires 33 and 34 by wire bonding.

Next, the ohmic electrodes 30a and 30b are formed on the back surface of the substrate 21, and Au (metal) wires 35 and 36 are wire bonded thereto, respectively. Note that, no metal electrode is formed on the front surface (upper surface) of the substrate 21 in a region between the ohmic electrodes 30a and 30b.

At this stage of fabrication process, the ohmic electrodes 30a and 30b are electrically in contact with each other through the substrate 21.

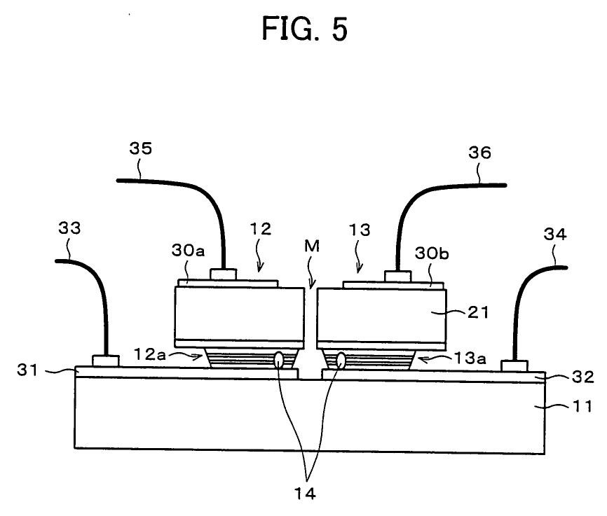

In the next step, as illustrated in FIG. 5, the substrate 21 and the buffer layer 22 are cut at a substantially midway point between the emission sections 12a and 13a, using a dicing device. Here, the midway point is chosen as a midway point M between the emission sections 12a and 13a (between the emission sources 14), i.e., a portion corresponding to the isolation groove isolating the emission sections 12a and 13a from each other.

The present laser device so obtained includes the laser elements 12 and 13 on the sub mount 11, as shown in FIG. 1.

As described, in the fabrication of the present laser device, a plurality of emission sources 14 are first formed on a single substrate 21 (emission source forming step).

Specifically, in the emission source forming step, semiconductor layers are stacked on the substrate 21 to monolithically form a series of emission sources 14 (FIG. 3(a)).

The emission sources 14 so formed are then isolated from one another by forming an isolation groove in the layer structure formed on the substrate 21, so that the emission sections 12a and 13a each include a single emission source 14 (emission source isolating step, FIG. 3(b)).

The substrate 21 with the emission sections 12a and 13a are mounted on the sub mount 11 (mounting step, FIG. 4).

Next, the substrate 21 mounted on the sub mount 11 is cut at a midway point M between the emission sections 12a and 13a, i.e., above the isolation groove isolating the emission sections 12a and 13a from each other (substrate cutting step).

As a result, the laser elements 12 and 13, each including a substrate 21 and an emission source 14, are formed on the sub mount 11. (The emission source 14 is included in each of the emission sections 12a and 13a of their respective laser elements 12 and 13.)

As described, in the fabrication of the present laser device, the emission sources 14 are first formed (monolithically) on the substrate 21 before the substrate 21 is mounted on the sub mount 11. Then, the substrate 21 and the layer structure thereon are cut between the emission sources 14, so as to form the laser elements 12 and 13 on the sub mount 11.

Accordingly, the present laser device includes a plurality of monolithically formed laser elements 12 and 13. This enables the relative positions (relative oscillating positions) of the laser elements 12 and 13 to be accurately maintained.

Further, because the substrate 21 is cut between the laser elements 12 and 13, the substrate 21 does not transfer heat or electricity. This greatly reduces thermal or electrical crosstalk between the laser elements 12 and 13, as in the hybrid laser device.

Further, when cutting the substrate 21 and the buffer layer 22 at the midway point M, the emission sections 12a and 13a that are formed on the epitaxial side of the substrate 21 (on the side where the emission sections 12a and 13a are formed) are already isolated from each other by the isolation groove formed by wet etching, as described above.

This enables the laser elements 12 and 13 to be completely isolated from each other by cutting the substrate 21 and the buffer layer 22. Further, this construction provides a safety margin for the sub mount 11, protecting the sub mount 11 from a dicing blade when a diamond or metal blade is used in the dicing (blade dicing).

Further, in applications where stealth dicing is used, the foregoing construction is also effective in protecting the electrode patterns 31 and 32 formed on the sub mount 11.

Further, because different techniques are used to cut the emission sections 12a and 13a and the substrate 21, an optimum cutting technique can be selected depending on the location to be cut (layer structure, substrate 21).

Further, in the fabrication of the present laser device, the substrate 21 and the buffer layer 22 are cut at the midway point M between the ohmic electrodes 30a and 30b where no metal electrodes are formed. This makes it easier to cut the substrate 21 and the buffer layer 22. In addition, the operator is able to easily check the progress of cutting by visual inspection.

Further, because the sub mount 11 used in the fabrication of the present laser device is an insulator (SiC), there is no electrical crosstalk through the sub mount 11.

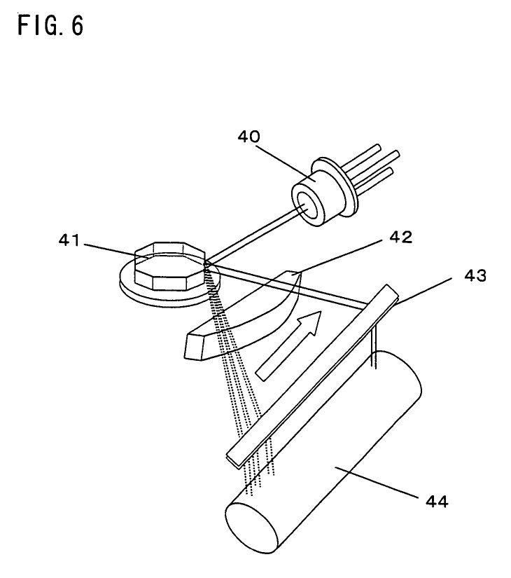

FIG. 6 is an explanatory view illustrating an engine (optical engine) of a laser beam printer using the present laser device.

In the configuration of FIG. 6, the laser elements 12 and 13 are configured to emit a red laser beam. The present laser device is packaged into a laser device 40.

The laser elements 12 and 13 in the laser device 40 respectively emit laser beams (see FIG. 1). The two laser beams are deflected by the polygon mirror 41, narrow through a lens (f-θ lens), and reflect on a mirror 43 into a photoreceptor 44. The polygon mirror 41 is rotated to scan the laser beams on the photoreceptor 44, thereby forming an electrostatic latent image on the photoreceptor drum 44. It should be noted here that scanning a single laser beam from one end to the other of the photoreceptor drum 44 only forms a single latent image line. With the laser device 40 of the configuration shown in FIG. 6, two latent image lines can be simultaneously formed.

Further, in the configuration of FIG. 6 using the present laser device, the accuracy of beam distance compares to that of the conventional monolithic semiconductor laser device. This makes it easier to set a desired distance (predetermined value) for the two lines.

It is preferable in the present laser device that the distance between the emission sections 12a and 13a of their respective laser elements 12 and 13 is wider than the distance between adjacent substrates 21 (buffer layers 22).

This is to prevent a leak current that is generated when the p-n junction formed by the overlying and underlying layers of the emission source 14 is damaged in mechanical dicing of the device from the substrate 21 side.

In the emission sections 12a and 13a, it is preferable that the exposed side surface of the layer structure, from the contact layer 28 to the active layer 24, has a single crystal plane, whereas the exposed side surface of the substrate 21 does not have a single crystal plane.

In this way, the side surface of the semiconductor structure (forming the contact layer 28, the active layer 24, and all the other layers in between) defining the isolation groove can have a specific crystal plane. This ensures that a leak current is prevented that occurs when the p-n junction formed by the overlying and underlying layers of the emission source 14 is damaged.

In the present embodiment, the emission sections 12a and 13a are isolated from each other using a wet etching technique (chemical removal of the layer material). With the wet etching, a crystal plane is exposed on the side surface (etched surface) of the emission sources 12a and 13a.

The emission sections 12a and 13a may be isolated from each other by dicing using water. In this case, the diced face is either a non-crystal plane or a rough surface of randomly oriented small crystal planes.

Alternatively, the emission sections 12 and 13 may be isolated from each other by dry etching, when the distance between the emission sections 12 and 13 is to be made wider than that between the substrates 21 (or the buffer layers 22). In this case, no crystal plane appears on the side surface of the emission sections 12a and 13a, as in dicing.

The substrate 21 and the buffer layer 22 may be diced using an ordinary metal blade, or by a dry stealth dicing technique developed by Hamamatsu Photonics K.K. Details of this technique are described in Document 1 below.

Document 1: Nikkei Press Release, “Photonics, Non-Contact High-Speed Cutting Technique Developed for Thin Wafer,” published on-line on Aug. 5, 2002, search made on Dec. 27, 2002. URL: http://release.nikkei.co.jp/detail.cfm?relID=28751.

The stealth dicing technique selectively forms a modifying layer with a dicing line by irradiation of a laser beam inside the substrate, wherein the substrate is cut by promoting a vertical growth of the modifying layer. The stealth dicing technique distinguishes itself from a common laser technique in that it provides a clean cut without producing dust or causing overheating.

Therefore, the stealth dicing technique does not require cleaning, and actually cuts the substrate only about 1 μm, making the technique more effective than common laser techniques. The stealth dicing technique is also effective in preventing a leak current that is caused when the p-n junction formed by the overlying and underlying layers of the emission source 14 is damaged.

The substrate 21 and the buffer layer 22 may be cut with a laser device using an excimer laser or CO₂ laser as the light source. Alternatively, the substrate 21 and the buffer layer 22 may be cut by etching.

The present laser device is generally used in package form, as described in, for example, Publication 4 (Japanese Publication for Unexamined Patent Application No. 267674/2001, Tokukai 2001-267674, published on Sep. 28, 2001).

In the following, an exemplary package of the present laser device is described.

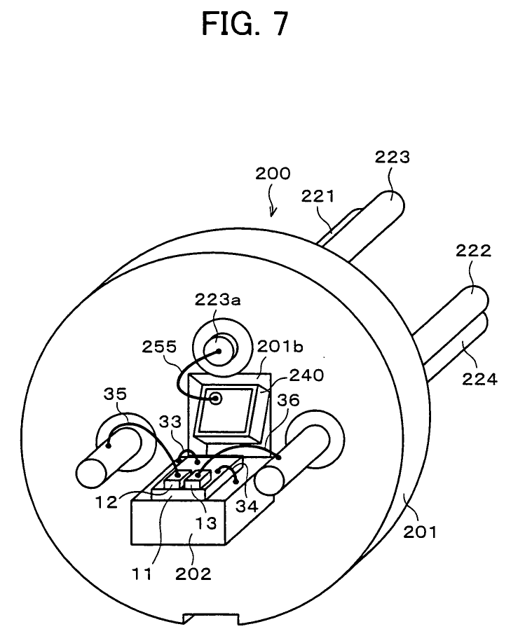

FIG. 7 is an explanatory view illustrating the package.

The package includes a metal stem 200 that is integral with a main body 201 and a heat-sinking substrate 202. Through the main body 201, lead pins 221 through 223 are provided, sticking out of the main body 201. The lead pins 221 through 223 are anchored on the main body 201 with low-melting point glass.

There is also provided a lead pin 224, which is a common terminal for the common electrode. One end of the lead pin 224 is directly anchored on the main body 201 so as to make electrical contact with the main body 201.

The heat-sinking substrate 202 is die bonded to the sub mount 11 of the present laser device, using a conductive paste (not shown).

The heat-sinking substrate 202 is also connected, via the Au wires 33 and 34, to the electrode patterns 31 and 32 of the laser elements 12 and 13.

In order to make electrical contacts between an external terminal of the package and the laser elements 12 and 13, the Au wires 35 and 36 (50 μm in diameter) connect the ohmic electrodes 30a and 30b of the laser elements 12 and 13 to the lead pins 221 and 222, respectively, which serve as the external terminal of the package.

In a recessed portion 201b of the main body 201, an MPD (Monitoring Photo detector) 240 is die bonded, using a conductive paste (not shown).

The MPD 240 has an upper electrode that is connected to an end face 223a of the lead pin 223 via a metal wire 255.

It should be noted here that the emission sources 14 in the laser elements 12 and 13 extend beyond the laser elements 12 and 13 in a direction perpendicular to the plane of paper in FIG. 1. Accordingly, the emission sources 14 also exist on the back of the laser elements 12 and 13.

In the configuration shown in FIG. 7, the MPD 240 detects the light that emerges from the back of the laser elements 12 and 13, so as to monitor a quantity of the laser beam emitted from the other side (front) of the emission source 14. Note that, the quantities of output laser beams from the front and back of the emission source 14 are not equal but are proportional to each other.

In the case where the sub mount 11 is made of a semiconductor material such as Si, the MPD 240 may be incorporated in the sub mount 11.

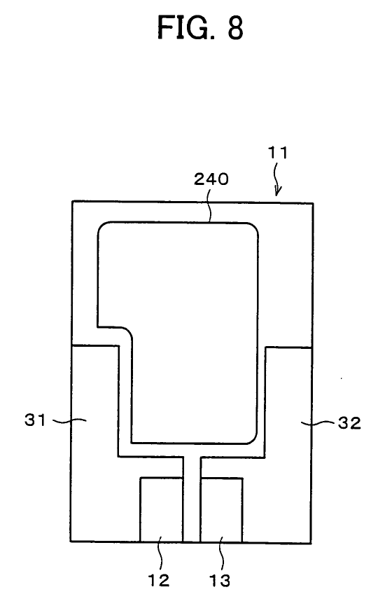

FIG. 8 is an explanatory view illustrating a structure in which the MPD 240 is mounted on the sub mount 11. In FIG. 8, the sub mount 8 is shown as viewed from above (from the side where the laser elements 12 and 13 are formed). FIG. 8 only shows a light receiving area (n-type Si substrate with a diffused p-type layer) of the MPD 240.

As shown in the figure, using a semiconductor material for the sub mount 11 is advantageous because it allows the MPD to be integrated with the laser elements 12 and 13 on the sub mount 11.

Further, by providing the MPD in the vicinity of the emission sources 14 in the laser elements 12 and 13, the outputs of the laser elements 12 and 13 can be monitored independently and simultaneously. This is suitable for electrical devices requiring such monitoring, including a laser beam printer (LBP), for example.

For efficient heat sinking, the sub mount 11 is preferably made of ceramic such as insulating SiC, instead of Si.

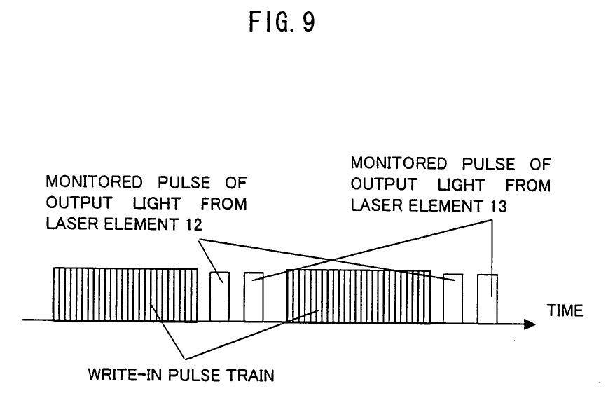

In order to monitor the two laser outputs, the output laser beams may be monitored, for example, at timings different from the write-in timing (formation of a latent image in LBP), as shown in FIG. 9.

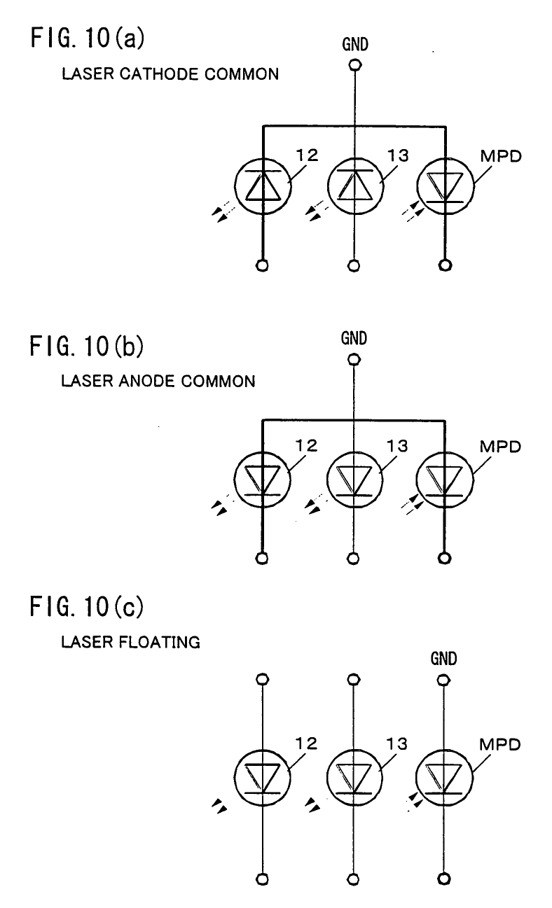

The wiring pattern of the present laser device may be of laser cathode common (FIG. 10(a)) or laser anode common (FIG. 10(b)), by changing the wiring pattern of the Au wires 33 and 34 and the Au wire 35 and 36 to the package, i.e., depending on which pair of the Au wires 33 and 34 and the Au wires 35 and 36 is connected to the common terminal of the package (a portion of the package in contact with the periphery, GND).

In cases where the package has five or more pins, the present laser device may have floating contact, in which none of the Au wires 33 through 36 is connected to the common terminal, as shown in FIG. 10(c).

The MPD shown in FIG. 10(a) through FIG. 10(c) is a monitoring photo detector as described above. The monitoring photo detector is provided on the sub mount 11 in a region where the laser elements 12 and 13 are not formed.

In the described embodiment, the present laser device includes two semiconductor laser elements, i.e., laser elements 12 and 13. However, not limited to this configuration, the present laser device may include three or more semiconductor laser elements.

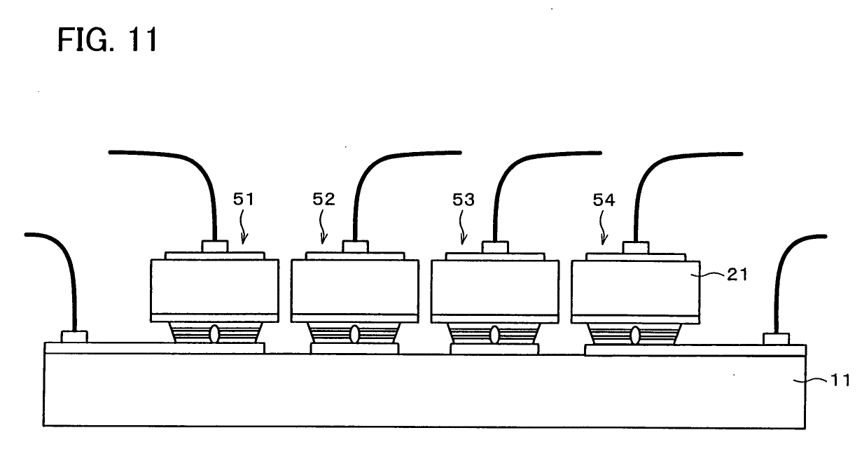

FIG. 11 is an explanatory view illustrating a configuration that provides four semiconductor laser elements 51 through 54, equivalent to the laser elements 12 and 13.

The configuration shown in FIG. 11 is fabricated in basically the same manner as that including the laser elements 12 and 13.

Specifically, the layer structure as shown in FIG. 3(a) is fabricated to include four emission sources (oscillating region), and the four emission sources so formed are isolated from one another by wet etching or other techniques (four semiconductor laser elements are monolithically formed).

After die bonding the semiconductor laser elements on the sub mount 11, the substrate 21 and the buffer layer 22 are cut into four pieces by dicing for example, so as to completely isolate the emission sources.

By integrating the four semiconductor laser elements, the configuration enables four latent lines to be simultaneously formed when used in a laser printer, thereby increasing a processing speed of a print job.

In the fabrication of the present laser device, the emission sections 12a and 13a (FIG. 3(b)) are formed by removing a central portion of the layer structure (FIG. 3(a)) until the buffer layer 22 is exposed. That is, an isolation groove is formed to the first clad layer 23.

However, the present invention is not just limited to this implementation, and the layer structure may be removed up to any layer (isolation groove may be formed to any layer). For example, the layer structure may be removed to the buffer layer 22 to expose the substrate 21.

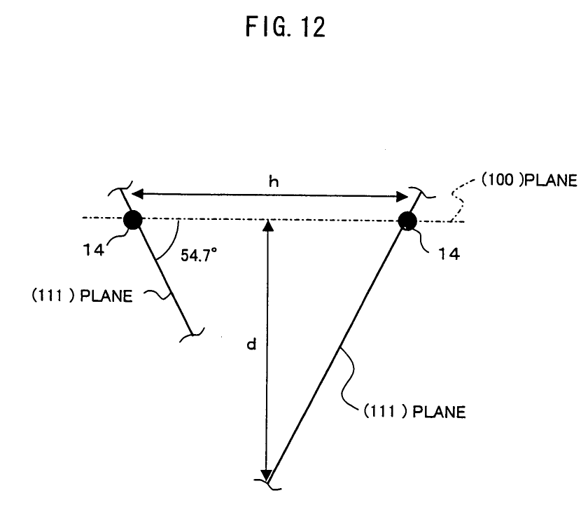

In other words, the isolation groove may extend over the buffer layer 22 and into the substrate 21. In general, the etched side surface of the trapezoid defining the isolation groove is slanted 54° with respect to the top plate, when a surface of the substrate 21 (semiconductor substrate) forming a crystal layer has a (100) plane, and a side surface of the trapezoid has a (111) plane, as shown in FIG. 12.

Thus, as shown in FIG. 12, when the depth d of the isolation groove is increased, the width h of the isolation groove (width along the emission sources) also increases. It is therefore preferable that the depth of the isolation groove be adjusted so that the width of the isolation groove does not reach or exceed the distance between the emission sources 14.

Generally, the distance between the buffer layer 22 and the emission source is less than 5 μm, and the thickness of the buffer layer 22 itself is less than 5 μm as well. Thus, even when the isolation groove is cut into the substrate 21, this additional distance is only about 10 μm.

Alternatively, formation of the isolation groove may be omitted altogether. In this case, the substrate 21 with the layer structure of FIG. 3(a) without the isolation groove is die bonded to the sub mount 11.

The substrate 21 and the layer structure are then simultaneously cut on the sub mount 11 (cut at a midway point of the emission sources 14).

By thus not forming the isolation groove, the fabrication of the present laser device can be simplified.

In the described embodiment, the sub mount 11 of the present laser device is made of an insulating Si material.

However, not limited thereto, the sub mount 11 may be made of SiC or AlN. In this case, a ceramic material of SiC AlN is preferably used.

Further, the sub mount 11 may be made of conductive Si. (Note: the Si semiconductor is a conductor, even though its resistance at room temperature is not as low as that of metals.) In this case, the electrode 29 is shared by the laser elements 12 and 13. The effect of preventing thermal crosstalk remains the same.

In the laser elements 12 and 13, the rate of heat transfer is the fastest through the layer material (from the substrate 21 to the contact layer 28). Accordingly, the adverse effect of thermal crosstalk is very small even when the laser elements 12 and 13 are in contact with each other via the sub mount.

In the described embodiment, the emission sections 12a and 13a are isolated from each other by etching the emission sections 12a and 13a in the form of a trapezoid. This can be carried out by slanting the opposing surfaces of the emission sections 12a and 13a in such a manner that the emission sections 12a and 13a taper toward the substrate 21.

However, the present invention is not just limited to this example, and the opposing surfaces of the emission sections 12a and 13a may be etched parallel to each other.

Preferably, the opposing faces of the emission sections 12a and 13a are of such geometry that allows the substrate 21 and the buffer layer 22 to be easily cut in a later step.

Further, in the described embodiment, the emission sections 12a and 13a are isolated from each other before cutting the substrate 21 and the buffer layer 22. However, not limited to this example, the structure as shown in FIG. 3(a) may be first die bonded to the sub mount 11 before forming the emission sections 12a and 13a, and all the layers (substrate 21 to contact layer 28) may be cut at once by etching or dicing.

Note that, the reason the emission sections 12a and 13a are isolated from each other before cutting the substrate 21 and the buffer layer 22 is to electrically isolate the laser elements 12 and 13 and thereby independently drive these two semiconductor laser elements.

Further, as described above, the sub mount 11 is made of an insulating material (Si). Thus, as long as it is not broken apart, the sub mount 11 can tolerate some damage when the substrate 21 and the buffer layer 22 are cut with a dicing blade, for example.

Further, in the described embodiment, the present laser device simultaneously emits two laser beams. However, as long as two or more laser elements are provided, these laser beams may be omitted one at a time.

Further, in the described embodiment, the laser elements 12 and 13 emit red laser beams. However, the laser elements 12 and 13 may be adapted to emit laser beams of other colors (infra red, blue, etc.), as required.

Further, in the described embodiment, the laser elements 12 and 13 of the present laser device are AlGaInP semiconductor lasers. However, the laser elements 12 and 13 are not just limited to this example, and may be any type of semiconductor laser.

Further, in the described embodiment, the present laser device includes the Au wires 33 through 36. However, the metal wires used in the present laser device may be made of other metals such as aluminum (Al), for example.

In one aspect of the invention, the present invention is a semiconductor laser device including a plurality of semiconductor laser elements on a sub mount, wherein a substrate of the semiconductor laser elements is spaced apart at wider intervals than a layer structure including emission sources.

In another aspect of the invention, the present invention is a semiconductor laser device including a plurality of semiconductor laser elements on a sub mount, wherein a side surface of a substrate with the semiconductor laser elements does not have a single crystal plane, whereas a side surface of a layer structure including emission sources and formed on the substrate has a single crystal plane.

As described above, the present invention provides a method for fabricating a semiconductor laser device including a plurality of semiconductor laser elements on a sub mount, the method including: an emission source forming step of stacking a semiconductor layer structure on a single substrate and forming a plurality of emission sources; a mounting step of mounting the substrate with the emission sources on the sub mount; and a substrate cutting step of cutting the substrate between the emission sources, so as to form a plurality of laser elements each including the substrate and an emission source.

The fabrication method of the present invention is used to fabricate a multi-beam laser device (MB laser device) used in electronic devices such as a laser beam printer or a CD/DVD player.

The MB laser device includes a plurality of laser elements (semiconductor laser elements) on a sub mount, so as to emit a plurality of laser beams.

The sub mount is a member used to install the laser elements on a metal stem (anchor) of the electronic device, and the sub mount serves to absorb stress that is generated due to different coefficients of thermal expansion of the laser elements and the metal stem.

The laser elements include a substrate and a semiconductor layer structure (layer structure including emission sources) formed on the substrate. As the term is used herein, “emission source” refers to a portion of the semiconductor layer structure where laser oscillation occurs (laser beam is emitted).

In order to fabricate such an MB laser device, the fabrication method first forms a plurality of emission sources on a single substrate.

Specifically, in this fabrication step, a semiconductor layer structure is formed on a single substrate, so as to (monolithically) form a series of emission sources.

In the next step of the fabrication method, the substrate with the emission sources is mounted on a sub mount in such a manner that the layer structure is disposed between the substrate and the sub mount (mounting step).

Next, the substrate mounted on the sub mount is cut between the emission sources (substrate cutting step). As a result, a plurality of laser elements are formed that includes the substrate and emission sources (i.e., layer structure including the emission sources) on the sub mount.

In this manner, the fabrication method of the present invention first forms a plurality of emission sources (monolithically) on a single substrate, and the substrate is mounted on the sub mount. Then, the substrate and the layer structure formed on the substrate are cut between the emission sources, so as to form a plurality of laser elements on the sub mount.

Therefore, the fabrication method of the present invention provides a semiconductor laser device that includes a plurality of monolithically formed laser elements. This enables the relative positions (relative oscillation positions) of the laser elements to be accurately maintained.

In the semiconductor laser device fabricated by the fabrication method of the present invention, the substrate is cut between the laser elements, thereby preventing transfer of heat and electricity through the substrate. This is effective in suppressing thermal or electrical crosstalk between the laser elements, as in the hybrid laser device.

Further, because the substrate is cut between the laser elements, the semiconductor laser device fabricated by the fabrication method of the present invention does not require electrical contacts through the substrate. This makes it possible to make electrical contacts for the laser elements not only in a cathode common layout (electrodes on the substrate side are commonly connected) but also in an anode common layout (electrodes on the sub mount side are commonly connected).

Further, depending on the wiring pattern of an external device installing the laser device, floating contacts (electrodes of the laser elements are not commonly connected) may be made.

It is preferable in the fabrication method of the present invention that the sub mount is an insulator. This prevents electrical crosstalk through the sub mount.

In the fabrication method of the present invention, the substrate cutting step may be carried out, for example, by any one of the following techniques: wet etching using chemicals (etchant) and a mask; dry etching using Ar (argon) gas and a mask; reactive dry etching using reactive gas such as CHCL₃, and a mask; blade dicing using a diamond or a metal blade; and stealth dicing (described later).

In the fabrication method of the present invention, it is preferable that the emission source forming step includes a step of cutting isolation grooves in the semiconductor layer structure of the substrate after forming the emission sources on the substrate, so as to isolate the emission sources from one another.

In the substrate cutting step of the fabrication method, the substrate is cut at portions corresponding to the isolation grooves (areas of extension of the isolation grooves).

That is, in the substrate cutting step, the substrate does not need to be cut near the sub mount (on the side of the layer structure). Thus, the sub mount will not be damaged by a blade even when blade dicing is used in the substrate cutting step.

Further, the fabrication method of the present invention allows different techniques to be easily used to cut the layer structure and the substrate. That is, the optimum cutting technique can be selected depending on the location to be cut (layer structure, substrate).

Preferably, the isolation grooves are cut at wider intervals than the substrate. In other words, it is preferable that the width of each isolation groove is wider than the distance between individual substrates cut in the substrate cutting step.

This prevents the p-n junction of the layer structure (p-n junction formed by the overlying and underlying layers of the emission sources) from being damaged when the substrate cutting step is mechanically carried out by dicing. As a result, there will be no leak current.

It is preferable that the isolation grooves are etched by wet etching, reactive dry etching, or other etching techniques.

In this way, a side surface of the isolation grooves (side surface of the isolated substrates) can have a specific crystal face in the semiconductor, preventing a leak current through the side surface.

Note that, a side surface of the isolation grooves cannot have a crystal face when the isolation grooves are formed by dicing, etc. In this case, a leak current may be caused.

A semiconductor laser device of the present invention (present laser device) is fabricated by the fabrication method described above.

Thus, the present laser device provides high accuracy for the relative positions (relative oscillation positions) of the laser elements. In addition, the present laser device can avoid inadvertent thermal and electrical crosstalk.

The wire layout of the laser elements may be any of a cathode common, anode common, and floating layout.

The side surface of the semiconductor materials (materials of the layers 24 through 28) defining the isolation groove (side surface of the isolated portion defining the isolation groove) has a specific crystal plane.

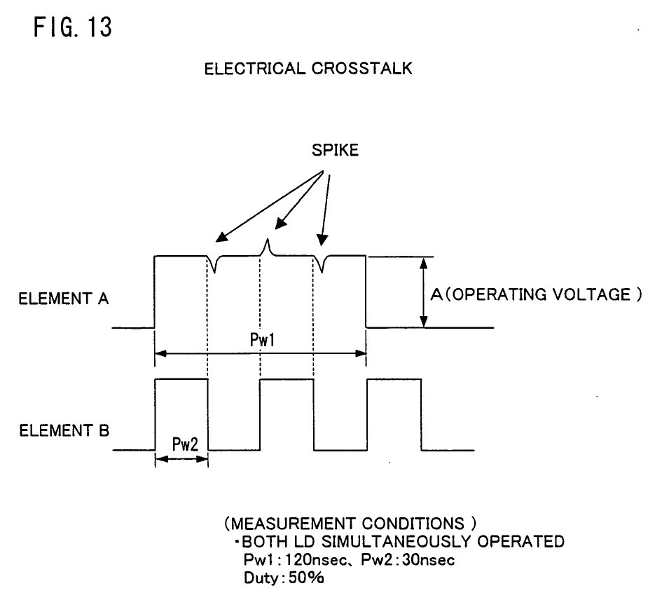

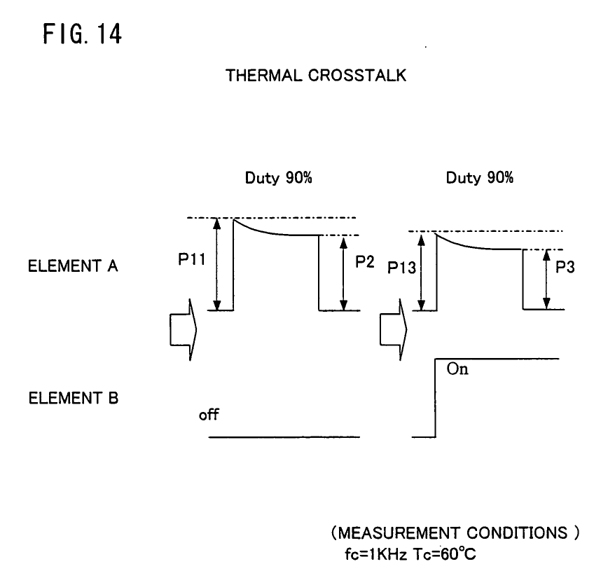

Conventionally, the monolithic structure has been marketed as a red dual-channel laser for copying machines, and a dual-wavelength laser for DVD. The dual-wavelength laser for DVD has also been available as a laser of the hybrid structure in which separate chips are individually mounted. In applications where a digital copying machine uses two channels for example, laser characteristics need to be independently controlled for each channel to deal with the spontaneous emission of light from the respective laser elements. In the monolithic structure (Publication 2), the laser elements are processed out of a single wafer, allowing the laser elements to be accurately positioned relative to each other. However, the laser characteristics fluctuate when the laser elements are turned ON simultaneously (when one laser element is turned ON while the other is ON). For example, an electrical spike is introduced into the driving voltage through the substrate (electrical crosstalk, FIG. 13), or the heat of oscillation transfers from one laser element to another, causing a substantial decrease in laser output (thermal crosstalk, the laser characteristics change as shown in FIG. 14). In this case, a print quality of a laser printer or a copying machine suffers. Note that, the notations Pw1 and Pw2 in FIG. 13 are pulse widths of the respective driving voltages for a first laser and a second laser. Further, in FIG. 14, a duty of 10% indicates a ratio of ON time with respect to the pulse width of the driving voltage. That is, the ON time of a laser element is 0.1 msec. when Pw1=1 msec. (fc=1 kHz) and duty=10%. It can be seen from this that the ON time increases and the laser output decreases as the duty increases.

In the hybrid structure (Publication 3), independent laser elements are separately packaged, and the respective laser elements are in contact with one another via the electrodes. Despite this, the heat of oscillation does not easily transfer from one laser element to another because the laser elements are separated by a highly insulating layer of air. However, owning to the fact that independent and individual laser elements are mechanically mounted, the accuracy of relative oscillation positions cannot match that of the monolithic structure. With the currently available mass-production technique, the monolithic structure provides a relative position accuracy of ±2 μm, whereas that of the hybrid structure is generally ±10 μm. In digital copying machines, the laser beams cannot be irradiated uniformly and a print quality suffers accordingly when the accuracy of the emission sources of the laser elements in a lasing direction is ±2 μm or greater. The hybrid structure offers flexible design in terms of wire layout because the electrodes are independently provided for the laser elements. However, this is not the case for the monolithic structure. For example, when a monolithic red laser is structured to provide adequate heat sinking by including the emission section on the side of the sub mount, the laser elements are provided on a GaAs substrate (n-type). This construction necessitates a cathode common layout, preventing use of an anode common laser driver.

Publication 2 attempts to solve the problem of electrical and thermal crosstalk by etching the active layer and other layers of a substrate that includes a plurality of laser elements. The present invention provides more effective heat sinking than the construction of Publication 2 in which the laser elements are formed on the same substrate, because, in the present invention, the laser elements are completely isolated from one another over their end faces.

In one aspect of the invention, the present invention provides first and second multi-beam semiconductor laser devices, and fabrication methods of the first and second semiconductor laser devices. The first multi-beam semiconductor laser device has a construction in which a plurality of laser elements are mounted on a single sub mount, wherein the semiconductor elements, form the surface of the epitaxial layer to the active layer, are separated from one another at wider intervals than the substrate.

The second multi-beam semiconductor laser device has a construction in which a plurality of laser elements are mounted on a single sub mount, wherein the exposed side surface of the layer structure from the epitaxial layer to the active layer has a single crystal plane, whereas the exposed side surface of the substrate does not have a single crystal plane.

The fabrication method of the first semiconductor laser device includes the steps of: making contacts in advance between the electrodes of a heat-sinking substrate (sub mount) such as SiC and the electrodes of a plurality of laser diode elements formed on a single (monolithic) semiconductor wafer, using an adhesive such as a conductive paste or a solder material; isolating only the laser diode elements from one another; and mounting the heat-sinking substrate on a laser package, with a plurality of laser chips mounted on the heat-sinking substrate.

In the fabrication method of the second semiconductor laser device, the laser element oscillating sections are isolated from one another by dicing using water, stealth dicing for cutting the laser material non-contact, or by etching the substrate.

In the foregoing devices and fabrication methods, a plurality of laser elements are monolithically fabricated, and contact is made to a heat-sinking substrate. In the next step, only the monolithic laser elements are isolated from one another by dicing. In this way, inadvertent crosstalk that might occur after the separation can be stabilized, while the monolithic structure ensures accuracy of oscillation positions. Further, since contact is made using electrodes and metal wires that are independently provided for each laser element, the wire layout of the laser elements may be of a cathode common or anode common layout.

Further, because the monolithically formed laser elements are anchored on the heat-sinking substrate by making contacts thereto, the position accuracy of the laser elements remains the same even after the dicing. Further, by the dicing, a layer of air is created between the laser elements, thereby effectively preventing crosstalk when the laser elements are driven simultaneously, as in the hybrid structure. The present invention is particularly effective for a red laser element, which poses more heat problem than the infrared laser. That is, the present invention combines the advantages of the monolithic structure and the hybrid structure, both structurally and characteristically. The present invention is also effective for laser elements that require more adequate heat sinking, including high output chips in particular. Further, because the electrodes are independently provided, different contacts can be made by changing the layout of metal leads. Further, a cathode common layout or an anode common layout may be selected by changing the polarity of the laser elements according to the characteristics of the laser driver.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

What is claimed is:

1. A method for fabricating a semiconductor laser device including a plurality of semiconductor laser elements on a sub mount,
said method comprising:
an emission source forming step of stacking a semiconductor layer structure on a single substrate and forming a plurality of emission sources;
a mounting step of mounting the substrate with the emission sources on the sub mount; and
a substrate cutting step of cutting the substrate between the emission sources, so as to form a plurality of laser elements each including the substrate and an emission source.

2. The method as set forth in claim 1, wherein:
said emission source forming step further comprises the step of forming isolation grooves in the semiconductor layer structure after forming the emission sources, so as to isolate the emission sources from one another.

3. The method as set forth in claim 2, wherein the isolation grooves are formed at greater intervals than the substrate.

4. The method as set forth in claim 3, wherein the isolation grooves taper toward the substrate.

5. The method as set forth in claim 2, wherein the isolation grooves are formed by etching.

6. The method as set forth in claim 2, wherein the isolation grooves in the semiconductor layer structure are defined by a specific crystal face of a semiconductor material of the semiconductor layer structure.

7. The method as set forth in claim 1, wherein the sub mount is an insulator.

8. The method as set forth in claim 7, wherein the sub mount is made of ceramic.

9. The method as set forth in claim 1, wherein the sub mount is a semiconductor.

10. The method as set forth in claim 1, wherein said substrate cutting step is carried out by any one of etching, blade dicing, and stealth dicing.

11. A semiconductor laser device including a plurality of semiconductor laser elements on a sub mount, said semiconductor laser device obtained by:
an emission source forming step of stacking a semiconductor layer structure on a single substrate and forming a plurality of emission sources;
a mounting step of mounting the substrate with the emission sources on the sub mount; and
a substrate cutting step of cutting the substrate between the emission sources, so as to form a plurality of laser elements each including the substrate and an emission source.

12. A laser beam printer including a semiconductor laser device that includes a plurality of semiconductor laser elements on a sub mount,
said laser beam printer obtained by:
an emission source forming step of stacking a semiconductor layer structure on a single substrate and forming a plurality of emission sources;
a mounting step of mounting the substrate with the emission sources on the sub mount; and
a substrate cutting step of cutting the substrate between the emission sources, so as to form a plurality of laser elements each including the substrate and an emission source.
